(19) United States
(12) Patent Application Publication
(10) Pub. No.: US 2023/0134728 A1
(43) Pub. Date: May 4, 2023

(54) MAGNETIC SENSOR FOR MEASURING AN EXTERNAL MAGNETIC FIELD ANGLE IN A TWO-DIMENSIONAL PLANE AND METHOD FOR MEASURING SAID ANGLE USING THE MAGNETIC SENSOR

(71) Applicant: CROCUS Technology SA, Grenoble (FR)

(72) Inventors: Robert Zucker, Half Moon Bay, CA (US); Scott Fritz, San Jose, CA (US)

(21) Appl. No.: 17/905,278

(22) PCT Filed: Feb. 22, 2021
(86) PCT No.: PCT/IB2021/051477

§ 371 Date: Aug. 30, 2022

Related U.S. Application Data
(60) Provisional application No. 62/983,812, filed on Mar. 2, 2020.

(51) Int. Cl. G01B 7/30; G01D 5/14

(52) U.S. Cl. CPC G01B 7/30; G01D 5/145

(57) ABSTRACT

Magnetic sensor for measuring an external magnetic field angle in a two-dimensional plane, including: a first and second sensing unit outputting, respectively, a first signal sin(θ) and a second signal cos(θ); a first multiplying DAC receiving the first signal and a first digital input sin(f*t) and outputting a first modulated output signal; a second multiplying DAC receiving the second signal and a second digital input cos(f*t) and outputting a second modulated output signal; a first RC filter receiving the first modulated output signal and outputting a first filtered signal sin(θ)*sin(f*t+RCd); a second RC filter receiving the second modulated output signal and outputting a second filtered signal sin(θ)*sin(f*t+RCd); an adder adding the first and second filtered signals and outputting a summed signal cos(f*t+RCd+θ); and an angle extracting unit for measuring the phase delay between the summed signal and a synchronization signal and determining the angle from the phase delay.

### FIELD

The present disclosure concerns a magnetic sensor for measuring an external magnetic field angle in a two-dimensional plane. The present disclosure further concerns a method for determining said angle using the magnetic sensor.

### DESCRIPTION OF RELATED ART

Measuring an orientation of an external magnetic field in a 2-dimensional plane can be performed by using a magnetic sensor. Such magnetic sensor can be formed by combining 1-dimensional magnetic sensors, wherein each 1-dimensional magnetic sensors is formed from four magnetic sensor elements arranged in a full (Wheatstone)-bridge circuit configuration. One of the 1-dimensional magnetic sensors has a sensing axis being orthogonal to the sensing axis of the other 1-dimensional magnetic sensor. A constant DC voltage can be supplied to the two 1-dimensional magnetic sensors, such that each 1-dimensional magnetic sensor generates outputs being supplied to the input terminals of a respective differential amplifier in order to obtain two digitized signals. The two digitized signals are inputted into a processing unit where software routine solves the arctangent of the ratio of the two digitized signals to extract the external magnetic field angle.

A disadvantage of the conventional 2-dimensional magnetic sensor is that it must perform cumbersome and lengthy mathematical operations which require a powerful processing unit. This approach is therefore power, time and cost intensive.

In the case of angular 2-d sensors having two TMR bridges that are magnetically polarized at a difference angle of 90° can produces a sine and cosine waveform signal. However, such sensor is imperfect and the two bridges are never exactly 90° apart. This is often referred to the issue of “orthogonality”.

### SUMMARY

The present disclosure concerns a magnetic sensor for measuring an external magnetic field angle in a two-dimensional plane, comprising: a first and second sensing unit outputting, respectively, a first signal sin(e) and a second signal cos(θ); a first multiplying DAC receiving the first signal and a first digital input sin(f*t) and outputting a first modulated output signal; a second multiplying DAC receiving the second signal and a second digital input cos(f*t) and outputting a second modulated output signal; a first RC filter receiving the first modulated output signal and outputting a first filtered signal sin(θ)*sin(f*t+RCd); a second RC filter receiving the second modulated output signal and outputting a second filtered signal sin(θ)*sin(f*t+RCd); an adder adding the first and second filtered signals and outputting a summed signal cos(f*t+RCd+θ); and an angle extracting unit for measuring the phase shift between the summed signal and a synchronization signal and determining the angle from the phase shift.

In an embodiment, the first and second sensing units comprise a plurality of TMR sensing elements arranged in full-bridge circuit.

The present disclosure further concerns a method for determining an rotational angle in a two-dimensional space of an external magnetic field, using the magnetic sensor.

The magnetic sensor and method disclosed herein allow for real-time update rates, with reduced power consumption and cost effectiveness with a compact IC solution. The magnetic sensor and method solves the issue of orthogonality.

### BRIEF DESCRIPTION OF THE DRAWINGS

The invention will be better understood with the aid of the description of an embodiment given by way of example and illustrated by the figures, in which:

FIG. 1 shows a TMR-based sensor comprising two sensing units, for measuring rotational angle in a two-dimensional space and an intensity of an external magnetic field;

FIG. 2 illustrates a possible configuration of the sensing unit;

FIG. 3 represents a sensing element comprising a self-referenced magnetic tunnel junction; and

FIG. 4 represents a portion of the magnetic sensor 10, according to an embodiment.

### DETAILED DESCRIPTION OF POSSIBLE EMBODIMENTS

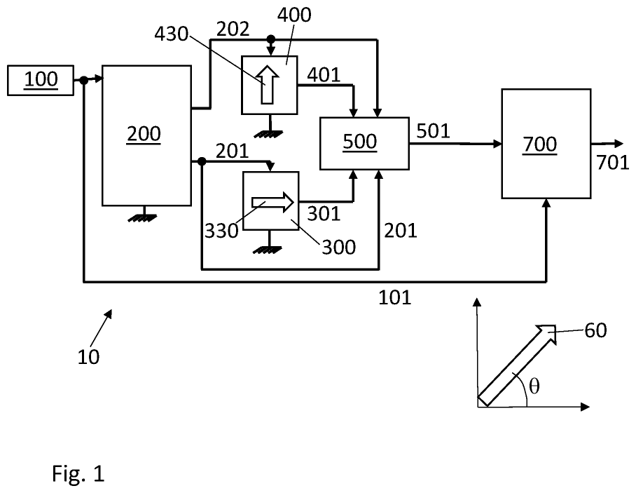

A TMR-based magnetic sensor 10 for measuring rotational angle θ in a two-dimensional plane of an external magnetic field 60 is shown in FIG. 1. The magnetic sensor 10 comprises a first sensing unit 300 outputting a first signal 301 and a second field sensing unit 400 outputting a second signal 401.

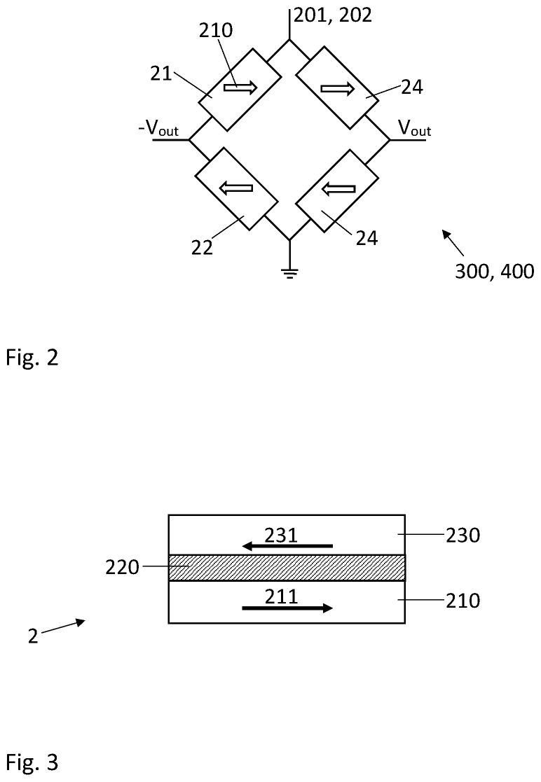

Each of the first sensing unit 300 and second magnetic field sensing unit 400 can comprise a plurality of TMR sensing elements arranged in full (Wheatstone)-bridge circuit, as illustrated in FIG. 2. In the arrangement of FIG. 2, the full-bridge circuit comprises two series connected TMR sensing elements 21, 22, in parallel to two other series connected magnetic field sensing elements 23, 24. Here, the first and second sensing units 300, 400 acts as a voltage divider, where the divider ratio is a function of the angle θ of the external magnetic field 60 in the two-dimensional space. Other arrangements of the TMR sensing elements are possible, such as half-bridge.

The sensing element 21-24 can comprise a self-referenced magnetic tunnel junction 2 (see FIG. 3) comprising a reference layer 230 having a fixed reference magnetization 230 and a sense layer 210 having a sense magnetization 211 that is orientable relative to the reference magnetization 231, according to a direction of the external magnetic field 60. A sensing axis of the sensing units 300, 400 coincides with the fixed orientation of the reference magnetization 231. In particular, a first sensing axis 330 of the first sensing unit 300 is set substantially orthogonal to a sensing axis 430 of the second sensing unit 400, for example by programming the direction of the reference magnetization 231.

The sensing element 21-24 is not limited to a self-referenced magnetic tunnel junction but can comprise a variety of elements that can sense a magnetic field. For instance, the sensing element can comprise a Hall Effect element, a magnetoresistance element or a magnetotransistor. As is known, there are different types of magnetoresistance elements, for example, a semiconductor magnetoresistance element such as Indium Antimonide (InSb), a giant magnetoresistance (GMR) element, an anisotropic magnetoresistance element (AMR), a tunneling magnetoresistance (TMR) element, a magnetic tunnel junction (MTJ), a spin-valve, etc.

The magnetic sensor 10 can further comprise a voltage generator 200 configured for supplying a first voltage waveform 201 to an input of the first magnetic field sensing unit 300, and a second voltage waveform 202 to an input of the second magnetic field sensing unit 400. The first and second voltage waveforms 201, 202 can comprise quadrature signals. For instance, the first voltage waveform 201 can comprise a sine waveform and the second voltage waveform 202 can comprise a cosine waveform. The first and second voltage waveforms 201, 202 have a periodic voltage waveform of fixed generator frequency f_{g} and amplitude. The first and second voltage waveforms 201, 202 are phase-shifted by substantially 90°.

The electronic circuit 10 can further comprise a clock generator 100 generating the clock synchronization signal 101. The synchronization signal 101 synchronizes the operation of the voltage generator 200.

The first sensing unit 300 outputs a first signal 301 and the second sensing unit 400 outputs a second signal 401. The amplitude of the first and second signals 301, 401 is changed relative to the amplitude of the first and second voltage waveforms 201, 202, depending on the orientation of the external magnetic field 60, i.e., relative to the angle θ of the external magnetic field 60 when the sensing element 21-24 are operating in the linear range.

The magnetic sensor 10 further comprises an adder circuit 500 into which the first and second signals 301, 401 are inputted. The adder circuit 500 is configured for adding (or summing) the first signal 301 to the second signal 401 and outputting a summed signal 501.

The magnetic sensor 10 further comprises an angle extracting unit 700. The summed signal 501 and the clock synchronization signal 101 are supplied to an input of the angle extracting unit 700. The synchronization signal 101 thus further synchronizes the operation of the angle extracting unit 700. The angle extracting unit 700 is configured for measuring a phase shift between the summed signal 501 and the synchronization signal 101 and for determining the angle θ of the external magnetic field 60 from the measured phase shift. The angle extracting unit 700 outputs a digital angle output 701 comprising the information about the determined angle θ.

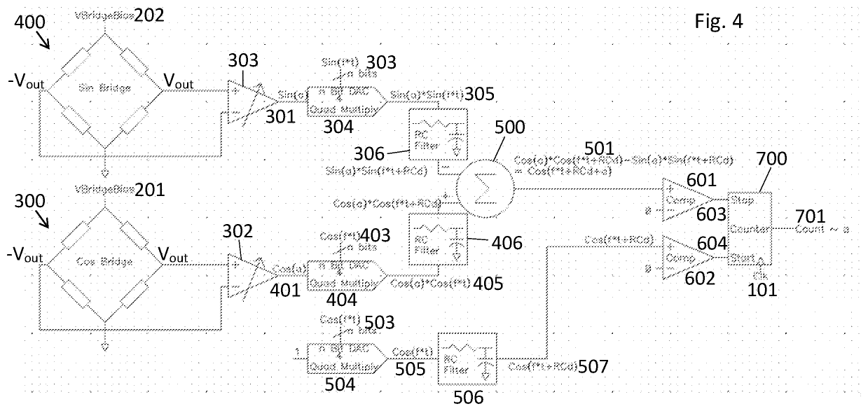

FIG. 4 represents the magnetic sensor 10, according to an embodiment. In FIG. 4, the voltage generator 200 and the clock generator 100 are not visible. The first voltage waveform 201 is inputted to an input of the full-bridge first sensing unit 300 and the second voltage waveform 202 is inputted to an input of the full-bridge second sensing unit 400. The voltage outputs −Vₒᵤₜ, Vₒᵤₜ of each of the two branches of the first and second sensing units 300, 400 are inputted in a first and second adjustable gain amplifier 302, 402 which adjusts for offset and sensitivity variation in the voltage outputs −Vₒᵤₜ, Vₒᵤₜ and output, respectively, the normalized first signal sin(θ) 301 and the normalized second signal cos(θ) 401.

The first signal sin(θ) 301 and a first digital input sin(f*t) 303 are inputted in a first multiplying DAC 304. The second signal cos(θ) 401 and a second digital input cos(f*t) 403 are inputted in a second multiplying DAC 404. Here, f is a frequency and t is time, where the product f*t is larger than the angle θ (f*t>>θ). The first multiplying DAC 304 outputs a first modulated output signal sin(θ)*sin(f*t) 305 and the second multiplying DAC 404 outputs a second modulated output signal cos(θ)*cos(f*t) 405. Preferably, the first and second multiplying DACs 304, 404 are 4-quadrant multiplying DACs.

The magnetic sensor 10 further comprises a first RC filter 306 receiving the first modulated output signal 305 and outputting a first filtered signal sin(θ)*sin(f*t+RCd) 307, where RCd is a phase delay caused by the first RC filter 306. A second RC filter 406 receives the second modulated output signal 405 and outputting a second filtered signal sin(θ)*sin(f*t+RCd) 407, where RCd is a phase delay caused by the second RC filter 406. The first filtered signal 307 is added to the second filtered signal 407 in the adder circuit 500. The a summed signal 501 (sin(θ)*sin(f*t+RCd) and cos(θ)*cos(f*t+RCd)) yields cos(a)*cos(f*t+RCd)−sin(θ)*sin(f*t+RCd) corresponds to cos(f*t+RCd+θ). The summed signal cos(f*t+RCd+θ) 501 is inputted in a comparator 601. Preferably, the first and second RC filters 306, 406 are configured such that ½*π*RC≈f.

The magnetic sensor 10 further comprises a reference multiplying DAC 504 inputted by an analog reference signal “1” 502 and a normalized reference digital input cos(f*t) 503, such as to give a reference modulated output signal cos(f*t) 505, where f>>θ. The reference modulated output signal 505 is inputted in a reference RC filter 506 such as to generate a reference output signal cos(f*t+RCd) 507, where RCd is a phase delay caused by the reference RC filter 506. The reference output signal cos(f*t+RCd) 507 is inputted in a reference comparator 602.

The external magnetic field angle θ can be determined from the phase delay RCd.

Preferably, the first, second and reference RC filters 306, 406, 506 have the same roll-off frequency.

The comparator 601 and the reference comparator 602 are configured for finding rising zero cross of, respectively, the summed signal 501 and the reference output signal 507. A comparator signal output 603 of the comparator 601 and a reference comparator signal output 604 of the reference comparator 602 are inputted in the angle extracting unit 700. Here, the angle extracting unit 700 is a counter. The counter 700 runs at a clock frequency greater than f such as to determine the angle θ.

The counter 700 can be configured to start counting when the reference output signal cos(f*t+RCd) 507 crosses zero and to stop counting when the summed signal cos(f*t+RCd+θ) 501 crosses zero. The angle θ is then proportional to the count.

In an embodiment, the complementary edges of the start and stop pulses of the clock synchronization signal 101 are used. This allows for doubling the update rate of the angle extracting unit 700.

In an embodiment, a method for determining an rotational angle θ in a two-dimensional space of an external magnetic field 60, using the TMR-based magnetic sensor 10, comprises the steps of:

input the first signal 301 of the first sensing unit 300 and the first digital input sin(f*t) 303 to the first multiplying DAC 304 to output the first modulated output signal sin(θ)*sin(f*t) 305;

input the second signal 401 of the second sensing unit 400 and the second digital input cos(f*t) 403 to the second multiplying DAC 404 to output the second modulated output signal cos(θ)*cos(f*t) 405;

input the first modulated output signal 305 in the first RC filter 306 and the second modulated output signal 405 in the second RC filter 406 to output, respectively, the first filtered signal sin(θ)*sin(f*t+RCd) 307 and the second filtered signal sin(θ)*sin(f*t+RCd) 407;

adding the first filtered signal (307) and the second filtered signal 407 in the adder circuit 500 to output the summed signal cos(f*t+RCd+θ) 501;

measuring the phase shift RCd between the summed signal 501 and the synchronization signal 101 in the angle extracting unit 700 and determining the angle θ from the measured phase shift RCd.

In an embodiment, the method further comprises providing inputting the summed signal 501 in the comparator 601 and finding rising zero cross of the summed signal 501.

In another embodiment, the method further comprises providing a first voltage waveform 201 to the first sensing unit 300 to output the first signal sin(θ) 301 and providing a second voltage waveform 202 to the second sensing unit 400 to output the second signal cos(θ) 401.

In yet another embodiment, the method further comprises inputting an analog reference signal 502 and a normalized reference digital input cos(f*t) 503 in the reference multiplying DAC 504 to output a reference modulated output signal cos(f*t) 505; and inputting the reference modulated output signal 505 in the reference RC filter 506 to generate the reference output signal cos(f*t+RCd) 507.

In yet another embodiment, the method further comprises inputting the reference output signal 507 in the reference comparator 602 and finding rising zero cross of the reference output signal 507.

One possible method is to skew (deviation, distort) the clocks that generate the digital sine and cosine modulation functions. In particular, imperfectly “orthogonal” first and second signals 301, 401 can be sampled and held and a programmable delay of several clock cycles can be added. This should allow the orthogonality to be corrected to the level of the angular resolution of the system.

### REFERENCE NUMBERS AND SYMBOLS

10 magnetic sensor
100 clock generator
101 clock synchronization signal
21-24 TMR sensing element
210 sense layer
211 sense magnetization
230 reference layer
231 reference magnetization
200 periodic voltage generator
201 first voltage waveform
202 second voltage waveform
300 first sensing unit
301 first signal
302 adjustable gain amplifier
303 first digital input
304 first multiplying DAC
305 first modulated output signal
306 first RC filter
307 first filtered signal
330 first sensing axis
350 capacitor
400 second sensing unit
401 second signal
402 adjustable gain amplifier
403 second digital input
404 second multiplying DAC
405 second modulated output signal
406 second RC filter
407 second filtered signal
430 second sensing axis
500 adder circuit
501 summed signal
502 analog reference signal
503 reference digital input
504 reference multiplying DAC
505 reference modulated output signal
506 reference RC filter
507 reference output signal
60 external magnetic field
601 comparator
602 reference comparator
603 comparator signal output
604 reference comparator signal output
700 angle extracting unit, counter
701 digital angle output
θ magnetic field angle
f frequency
f_{g} fixed frequency, generator frequency
RCd phase delay
t time
V voltage

1. A magnetic sensor for measuring an angle (θ) of an external magnetic field in a two-dimensional plane, comprising:
a first sensing unit outputting a first signal sin(θ) and a second field sensing unit outputting a second signal cos(θ);
a first multiplying DAC receiving the first signal sin(θ) and a first digital input sin(f*t) and outputting a first modulated output signal sin(θ)*sin(f*t), where f is a frequency and t is time;
a clock generator generating a clock synchronization signal;
a second multiplying DAC receiving the second signal cos(θ) and a second digital input cos(f*t) and outputting a second modulated output signal cos(θ)*cos(f*t);
a first RC filter receiving the first modulated output signal and outputting a first filtered signal sin(θ)*sin(f*t+RCd);
a second RC filter receiving the second modulated output signal and outputting a second filtered signal sin(θ)*sin(f*t+RCd), where RCd is a phase delay caused by the first and second RC filter;
an adder configured for adding the first filtered signal with the second filtered signal and outputting a summed signal cos(f*t+RCd+θ); and
an angle extracting unit configured for measuring the phase delay (RCd) between the summed signal and the clock synchronization signal (101) using a reference output signal cos(f*t+RCd), and for determining the angle from the phase delay (RCd).

2. The magnetic sensor according to claim 1, further comprising a comparator receiving the summed signal and configured for finding rising zero cross of the summed signal.

3. The magnetic sensor according to claim 2, wherein the angle extracting unit is a counter configured to start counting when the reference output signal cos(f*t+RCd) crosses zero and to stop counting when the summed signal cos(f*t+RCd+θ) crosses zero, the angle being proportional to the count.

4. The magnetic sensor according to claim 3, further comprising:
a reference multiplying DAC receiving an analog reference signal and a normalized reference digital input cos(f*t) and outputting a reference modulated output signal cos(f*t); and
a reference RC filter configured for generating the reference output signal cos(f*t+RCd) from inputted reference modulated output signal.

5. The magnetic sensor according to claim 4, wherein the reference output signal is inputted in a reference comparator configured for finding rising zero cross of the reference output signal.

6. The magnetic sensor according to claim 3, wherein the counter runs at a clock frequency greater than f.

7. The magnetic sensor according to claim 6, wherein f*t larger than the angle.

8. The magnetic sensor according to claim 1, wherein the first and second multiplying DAC are a four quadrant multiplying DAC.

9. The magnetic sensor according to claim 1, wherein the first and second sensing units comprise a plurality of TMR sensing elements arranged in full-bridge circuit.

10. A method for determining an rotational angle θ in a two-dimensional space of an external magnetic field, using a magnetic sensor comprising:
a first sensing unit outputting a first signal sin(θ) and a second field sensing unit outputting a second signal cos(θ);
a first multiplying DAC receiving the first signal sin(θ) and a first digital input sin(f*t) and outputting a first modulated output signal sin(θ)*sin(f*t), where f is a frequency and t is time;
a clock generator generating a clock synchronization signal;
a second multiplying DAC receiving the second signal cos(θ) and a second digital input cos(f*t) and outputting a second modulated output signal cos(θ) *cos(f*t);
a first RC filter receiving the first modulated output signal and outputting a first filtered signal sin(θ) *sin(f*t+RCd);
a second RC filter receiving the second modulated output signal and outputting a second filtered signal sin(θ)*sin(f*t+RCd), where RCd is a phase delay caused by the first and second RC filter;
an adder configured for adding the first filtered signal with the second filtered signal and outputting a summed signal cos(f*t+RCd+θ); and
an angle extracting unit configured for measuring the phase delay (RCd) between the summed signal and the clock synchronization signal (101) using a reference output signal cos(f*t+RCd), and for determining the angle from the phase delay (RCd);
the method comprising:
inputting the first signal of the first sensing unit and the first digital input sin(f*t) to the first multiplying DAC to output the first modulated output signal sin(θ)*sin(f*t);
inputting the second signal of the second sensing unit and the second digital input cos(f*t) to the second multiplying DAC to output the second modulated output signal cos(θ)*cos(f*t);
inputting the first modulated output signal in the first RC filter and the second modulated output signal in the second RC filter to output, respectively, the first filtered signal sin(θ)*sin(f*t+RCd) and the second filtered signal sin(θ)*sin(f*t+RCd);
adding the first filtered signal and the second filtered signal in the adder circuit to output the summed signal cos(f*t+RCd+θ);
measuring the phase delay (RCd) between the summed signal and the clock synchronization signal using a reference output signal cos(f*t+RCd) in the angle extracting unit, and determining the angle from the measured phase delay (RCd).

11. The method according to claim 10, further comprising providing a first voltage waveform to the first sensing unit to output the first signal sin(θ) and providing a second voltage waveform to the second sensing unit to output the second signal cos(θ).

12. The method according to claim 10,
wherein the magnetic sensor further comprises a comparator; and
wherein the method further comprises inputting the summed signal in the comparator and finding rising zero cross of the summed signal.

13. The method according to claim 12,
wherein the magnetic sensor further comprises a reference multiplying DAC and a reference RC filter; and
wherein the method further comprises inputting an analog reference signal and a normalized reference digital input cos(f*t) in the reference multiplying DAC to output a reference modulated output signal cos(f*t);
and inputting the reference modulated output signal in the reference RC filter to generate the reference output signal cos(f*t+RCd).

14. The method according to claim 13,
wherein the magnetic sensor further comprises a reference comparator; and
wherein the method further comprises inputting the reference output signal in the reference comparator and finding rising zero cross of the reference output signal.
